(19) United States
(12) Patent Application Publication
(10) Pub. No.: US 2018/0288889 A1
(43) Pub. Date: Oct. 4, 2018

(54) CIRCUIT BOARD AND BATTERY ARCHITECTURE OF AN ELECTRONIC DEVICE

(71) Applicant: Google Inc., Mountain View, CA (US)

(72) Inventors: Paul Lynn Fordham, Wauconda, IL (US); David Kyungtag Lim, Glenview, IL (US)

(21) Appl. No.: 15/474,253

(22) Filed: Mar. 30, 2017

(51) Int. Cl. H05K 5/00; H01R 12/79; H01R 43/26; H01R 12/77; H05K 7/14; H05K 1/18; H01M 2/30; H01M 2/02; H01M 10/42

(52) U.S. Cl. CPC H05K 5/0086; H01M 2220/30; H01R 43/26; H01R 12/777; H05K 5/0017; H05K 7/1417; H05K 1/18; H01M 2/30; H01M 2/021; H01M 10/425; H01R 2201/16; H05K 2201/10151; H05K 2201/10113; H05K 2201/10121; H05K 2201/10083; H05K 2201/04; H01R 12/79

(57) ABSTRACT

An electronic device is provided. In some embodiments, the electronic device includes an a battery having a first electrical connector at a first end, a second electrical connector at a second end, and electrical conductors extending from the first connector to the second connector, a first circuit board connected to the first connector, and a second circuit board connected to the second connector. The first circuit board is electrically connected with the second circuit board through the electrical conductors.

### BACKGROUND

Electronic devices typically include a circuit board and other components. Many electronic devices include multiple circuit boards that are positioned inside a housing along with other components, such as a battery. For example, mobile electronic devices, such as mobile phones, may include top and bottom circuit boards arranged at top and bottom locations within an electronic device housing, and a battery positioned between the top and bottom boards. Various techniques have been employed to electrically connect top and bottom boards, such as routing a flexible circuit over a major surface of a battery that is located between the top and bottom boards. Top and bottom boards have also been electrically connected using a flexible circuit routed alongside the battery, or a printed circuit board positioned in a C-shaped or side-board configuration.

### SUMMARY

In general, this disclosure describes devices, systems, and methods related to battery and circuit board configurations in electronic devices. Example electronic devices may include first and second circuit boards that are electrically connected via a battery and positioned within an electronic device housing. The battery may be positioned between the first circuit board and the second circuit board, and include electrical conductors that provided electrical connection between the first circuit board and the second circuit board. Such configurations can provide space savings that allow larger or additional components to be accommodated within the electronic device, such as a larger battery having an improved capacity. Alternatively or additionally, the overall size of electronic devices employing such configurations may be reduced.

Embodiment 1 is an electronic device, comprising: a battery comprising a first electrical connector at a first end of the battery, a second electrical connector at a second end of the battery, and one or more electrical conductors extending from the first connector to the second connector; a first circuit board connected to the first connector; and a second circuit board connected to the second connector, wherein the first circuit board is electrically connected to the second circuit board by the one or more electrical conductors.

Embodiment 2 is the electronic device of embodiment 1, wherein the first circuit board is electrically connected to the second circuit board only by the one or more electrical conductors of the battery.

Embodiment 3 is the electronic device of any of the preceding embodiments, further comprising a display connected to the first circuit board, wherein: the first circuit board includes at least one of: a speaker, a front facing camera, a proximity sensor, a microphone, and a camera flash, and the second circuit board includes at least one of: an electrical connector, an audio connector, a microphone, and a vibrator.

Embodiment 4 is the electronic device of any of the preceding embodiments, further comprising positive and negative electrode terminals electrically connected to an electrode assembly of the battery, the positive and negative electrode terminals configured to receive electrical power that is generated by chemical reactions in the electrode assembly.

Embodiment 5 is the electronic device of any of the preceding embodiments, wherein the battery comprises a pouch and an electrode assembly within the pouch.

Embodiment 6 is the electronic device of any of the preceding embodiments, wherein the pouch comprises a flexible circuit substrate layer at least partially surrounding the electrode assembly.

Embodiment 7 is the electronic device of any of the preceding embodiments, wherein the flexible circuit substrate layer comprises a polyamide.

Embodiment 8 is the electronic device of any of the preceding embodiments, wherein the flexible circuit substrate layer comprises a battery protection circuit.

Embodiment 9 is the electronic device of any of the preceding embodiments, wherein the flexible circuit substrate layer comprises an NFC circuit.

Embodiment 10 is the electronic device of any of the preceding embodiments, wherein the flexible circuit substrate layer comprises RF transmission lines.

Embodiment 11 is the electronic device of any of the preceding embodiments, further comprising an electronic device housing, wherein the first circuit board is positioned in a top region of the housing and the second circuit board is positioned in a bottom region of the housing.

Embodiment 12 is the electronic device of any of the preceding embodiments, wherein the battery is positioned between the first circuit board and the second circuit board.

Embodiment 13 is the electronic device of any of the preceding embodiments, wherein the first circuit board, the second circuit board, and the electrical conductors of the battery together extend along an entire length of the electronic device housing, and the first circuit board and the second circuit board each extend across an entire width of the electronic device housing.

Embodiment 14 is the electronic device of any of the preceding embodiments, wherein the battery has first and second major planar faces separated by sidewalls, the first major face and the second major face oriented parallel to the first circuit board and the second circuit board.

Embodiment 15 is the electronic device of any of the preceding embodiments, wherein the electrical conductors extend along a sidewall of the battery between the first connector and the second connector.

Embodiment 16 is an electronic device battery, comprising: an electrode assembly; a pouch surrounding the electrode assembly and including a flexible circuit substrate layer; a first electrical connector at a first end; a second electrical connector at a second end; and one or more electrical conductors extending from the first connector to the second connector on the flexible circuit substrate layer.

Embodiment 17 is the electronic device battery of embodiment 16 wherein the flexible circuit substrate layer comprises a battery protection circuit.

Embodiment 18 is the electronic device of any of embodiment 16 and/or 17, wherein the one or more electrical conductors are not electrically connected with the electrode assembly.

Embodiment 19 is a method of manufacturing an electronic device, comprising: securing a first circuit board at a first position within an electronic device housing; securing a second circuit board at a second position within the electronic device housing; positioning a battery in a space within the electronic device housing defined between the first position and the second position, the battery having a first electrical connector, a second electrical connector, and one or more electrical conductors between the first and second electrical connectors; and connecting the first circuit board to the first electrical connector and the second circuit board to the second electrical connector.

Embodiment 20 is the method of embodiment 19, wherein the battery provides an only electrical connection between the first circuit board and the second circuit board.

Embodiments described herein may provide one or more of the following benefits. First, some configurations described herein allow an electronic device to be physically smaller. Electrical connection between first and second boards provided through a battery can alternatively facilitate positioning of larger or additional components within the electronic device housing. For example, the presence of an additional printed circuit board, a flexible printed circuit, or another electrical connector between first and second circuit boards (e.g., separate from the battery) may be reduced in size or eliminated. A circuit board configuration in which first and second boards are electrically connected via the battery can also facilitate positioning of relatively larger components, such as a larger battery, within the electronic device housing in a space-efficient manner.

Second, some configurations described herein may improve the usable time of an electronic device between charges by accommodating a battery having a larger volume or capacity. For example, electrical conductors extending through battery packaging may allow the battery to have a relatively larger volume and/or capacity (e.g. amp-hours available when discharged at a particular discharge current), than if the battery were positioned along with an additional printed circuit board or an additional flexible printed circuit joining the first and second circuit boards.

Third, battery constructions described herein may increase the flexibility in manufacturing and assembly of an electronic device. For example, one or more additional electronic components may be included as part of the battery, and assembled with the electronic device housing by installing the battery. The first circuit board, second circuit board, and battery may be assembled with each other and other components of the electronic device in a desired sequence. Furthermore, in some embodiments, design and assembly of electronic devices may be simplified by eliminating the need for components that may otherwise be required to connect circuit boards that are separated by a battery.

Fourth, battery and circuit board configurations described herein, such as top and bottom circuit boards connected by electrical conductors provided in a layer of a battery packaging, can provide flexibility in arranging and assembling other components within the electronic device. For example, electrical conductors provided along a thickness of the battery packaging can provide robust connection with a user input (e.g., button, switch, etc.) on a sidewall of the electronic device housing, and/or facilitate positioning of larger or additional components within the electronic device housing.

The details of one or more embodiments are set forth in the accompanying drawings and the description below. Other features and advantages will be apparent from the description and drawings, and from the claims.

### DESCRIPTION OF THE DRAWINGS

The details of one or more embodiments are set forth in the accompanying drawings and the description below.

FIG. 1 is a perspective exploded view of an electronic device having first and second circuit boards connected by a battery.

FIG. 2 is a front view of the electronic device of FIG. 1.

FIG. 3 is a perspective view of an example battery.

FIG. 4 is a perspective view of the example battery of FIG. 3.

FIG. 5 is a perspective view of the example battery of FIG. 3.

FIG. 6 is a perspective view of the example battery of FIG. 3.

FIG. 7 is a partial cross-sectional view of the example battery of FIG. 3.

FIG. 8 is a perspective view of an example battery.

FIG. 9 is a plan view of an electrical connector.

FIG. 10 is a flow diagram of a method of manufacturing an electronic device.

### DETAILED DESCRIPTION OF ILLUSTRATIVE EMBODIMENTS

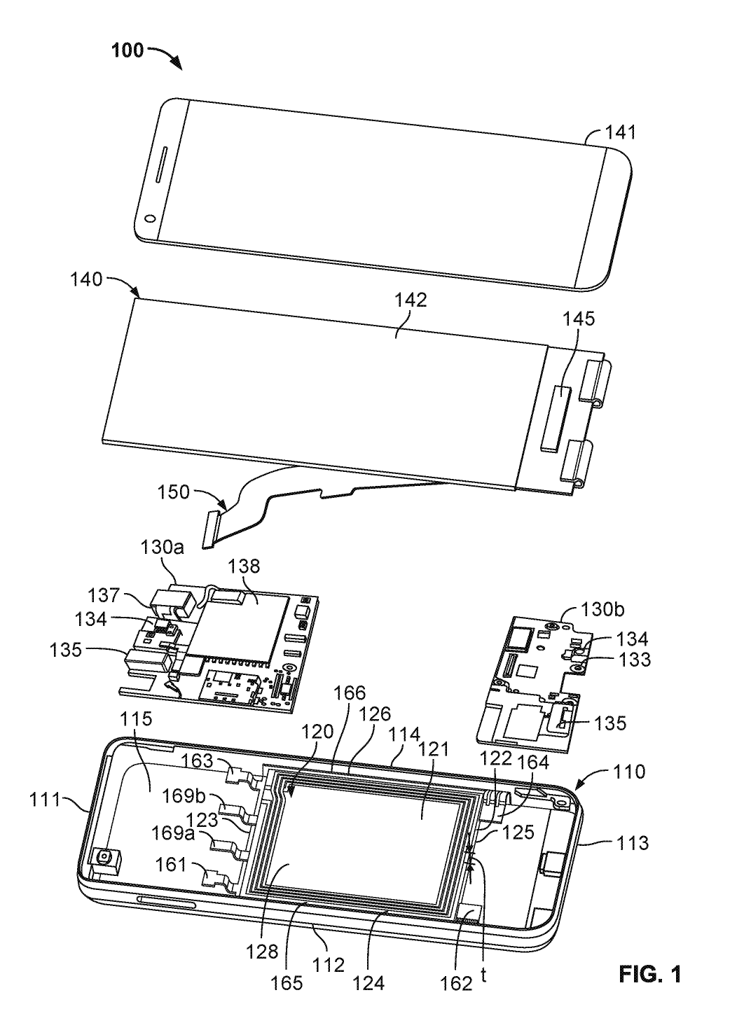

Referring to FIG. 1, an example electronic device 100 is shown, including an electronic device housing 110, a battery 120, a circuit board 130 and a display assembly 140. Circuit board 130 includes first and second circuit boards 130a, 130b that electrically connect various components of electronic device 100. First and second circuit boards 130a, 130b, are connected to each other by electrically conductors of battery 120. Battery 120 electrically connects first and second circuit boards 130a, 130b in a space-efficient manner such that larger or additional components can be accommodated within electronic device housing 110 with first and second circuit boards 130a, 130b than if other circuit board architectures were employed.

Electronic device 100 may be an electronic device including a display, such as a mobile phone, music player, tablet, laptop computing device, wearable electronic device, data storage device, display device, adapter device, desktop computer, or other electronic device.

Electronic device housing 110 may be a bucket-type enclosure having first, second, third, and fourth side portions 111, 112, 113, 114 that define outer sidewalls of electronic device 100, and a major planar face 115 integrally attached with side portions 111, 112, 113, 114. A bucket-type enclosure allows components of electronic device 100 to be accommodated within housing 110 and enclosed by an outer cover, such as outer cover 141. In other embodiments, one or more side portions 111, 112, 113, 114, and/or back major planar face 115 may be formed separately and subsequently joined together (e.g., with one or more adhesives, welds, snap-fit connectors, fasteners, etc.) to form electronic device housing 110. In various embodiments, electronic device housing 110 may be an H-beam type housing or other electronic device housing 110 that includes one or more walls that provide a housing to at least partially support and/or enclose components of electronic device 100.

Electronic device housing 110 is made from a material that provides adequate structural rigidity to support and protect internal components of electronic device 100. In some embodiments, electronic device housing 110 is formed from a single piece of metal. Electronic device housing 110 may be milled, molded, forged, etched, printed, or otherwise formed. Alternatively or additionally, electronic device housing 110 may be formed from plastic, glass, wood, carbon fiber, ceramic, combinations thereof, and/or other materials.

Electronic device housing 110 and an outer cover 141 define an interior volume that can house various components of electronic device 110, including battery 120, circuit board 130, and display assembly 140. Electronic device housing 110 can accommodate additional components of electronic device 100, such as microphone 133, speaker 134, sensors 135, such as fingerprint sensors, proximity sensors, accelerometers, and/or other sensors, camera assembly 136, flash devices 137, processor 138, antennas, and/or other components. In various embodiments, some or all of these components may be electrically connected with circuit board 130.

Display assembly 140 provides a user interface display that displays information to a user. For example, display assembly 140 may provide a touch screen display that a user can interact with to view displayed information and to provide input to electronic device 100. In some embodiments, display assembly 140 occupies substantially all or the majority of a front major face 116 of electronic device 100 (e.g., and covers battery 120 and first and second circuit boards 130a, 130b), and includes a rectangular visible display.

Display assembly 140 includes one or more substrate layers that provide the visible display and/or allow display assembly 140 to receive touch input from a user. For example, outer cover 141 may serve as an outermost layer that encloses other components of display assembly 140 and electronic device 100, and that a user may physically touch to provide input to electronic device 100. In some embodiments, display assembly 140 includes a liquid crystal display (LCD) panel 142 including a liquid crystal material positioned between one or more color filter and thin-film-transistor (TFT) layers. The layers of display panel 142 may include substrates formed from glass or polymer, such as polyamide. In various embodiments, display assembly 140 may be a light-emitting diode (LED) display, an organic light-emitting diode (OLED) display, such as an active-matrix organic light-emitting diode (AMOLED) display, a plasma display, an electronic ink display, or another display that provides visual output to a user.

Display assembly 140 includes driver circuitry used to control display output and/or receive user input. In some embodiments, driver circuitry includes a display integrated circuit 145 that is mounted in electrical communication with the TFT layers of display panel 142, for example by gate lines or other electrical connection. Display integrated circuit 145 may receive display data from processor 138, for example, and deliver corresponding signals to control the optical properties of a liquid crystal layer, for example, to produce a visible output.

Connection between display integrated circuit 145 and circuit board 130 (and processor 138, for example) may be provided by an electrical conductor that facilitates a robust electrical connection while maintaining a low profile configuration that does not significantly increase the overall dimensions of electronic device 100. In some embodiments, a flex conductor 150 connects display integrated circuit 145 and circuit board 130. Flex conductor 150 includes conductive structures on a thin, flexible substrate. Flex conductor 150 has a relatively thin profile and may be bent along a longitudinal direction to fit between various components of electronic device 100, such as to connect from a front face of a display substrate to circuit board 130 by passing between battery 120 and a rear of display assembly 140. Flex conductor 150 may be connected between the display integrated circuit 145 and the first circuit board 130a (e.g., a top circuit board proximate top wall 111 of electronic device housing 110) or second circuit board 130b (e.g., a bottom circuit board proximate bottom wall 113 of electronic device housing 110). Alternatively or additionally, further electrical communication between display assembly 140 and the other of first circuit board 130a or second circuit board 130b is provided via electrical conductors of battery 120.

Components of display assembly 140 and flex conductor 150 may be positioned within electronic device 100 such that the space required to connect display assembly 140 with circuit board 130 is reduced. In some embodiments, display integrated circuit 145 may be positioned at a bottom of display substrate 142 (e.g., a portion of display substrate 142 close to bottom wall 113) and flex conductor 150 wraps around a back side of display substrate 142 to connect with first and/or second circuit boards 130a, 130b. In some embodiments, display integrated circuit 145 may be positioned at a top of display substrate 142 (e.g., a portion of display substrate 142 close to top wall 111) and flex conductor 150 wraps around a back side of display substrate 142 to connect with first and/or second circuit boards 130a, 130b. In some embodiments, display integrated circuit 145 may be positioned along a side of display substrate 142 (e.g., a side portion of display substrate 142 close to side portion 112 or side portion 114 of electronic device housing 110) and flex conductor wraps around a back side of display substrate 142 to connect with first and/or second circuit boards 130a, 130b. In some embodiments, display integrated circuit 145 and flex conductor 150 are positioned so that flex conductor 150 does not extend between display assembly 140 and battery 120. Positioning the battery 120 directly adjacent display assembly 140 (e.g., without an intervening electrical conductor 150 passing between battery 120 and display assembly 140) facilitates an increased battery size having a greater power capacity.

Conductive structures of flex conductor 150 may include conductive lines, printed conductive traces, or other conductive components that provide electrical connection between respective electrical contacts associated with display integrated circuit 145 and circuit board 130. Flex conductor 150 may be a single, double, or multi-layer flexible printed circuit including a polyamide, PEEK, polyester, having printed or laminated conductive elements, for example. Such construction provides robust electrical characteristics that can provide reliable connection between various components while having a low bending radius to facilitate compact arrangement of flex conductor 150 within electronic device 100.

Battery 120 is positioned within electronic device housing 110. In some embodiments, battery 120 is positioned substantially centrally and/or towards a bottom region of electronic device housing 110 that may promote a user's perception of stability when electronic device 100 is handled. For example, battery 120 may be positioned adjacent to first and second circuit boards 130a, 130b such that battery 120 is positioned substantially centrally between top and bottom sidewalls 111, 113. The first and second circuit boards 130a, 130b, are arranged at top and bottom positions within the electronic device housing along a y-axis extending between top and bottom walls 111, 113, and battery 120 is positioned substantially centrally along the y-axis. In other embodiments, battery 120 may be positioned in a stacked configuration such that circuit boards 130a and/or 130b are between battery 120 and display assembly 140 (e.g., sandwiched between battery 120 and display assembly 140), or vice versa.

Battery 120 provides a primary source of power for electronic device 100 and its components. Battery 120 may include a secondary cell, rechargeable battery configured for use through thousands of battery charging cycles over the entire useful life of electronic device 100, for example. In various embodiments, battery 120 may be a lithium polymer battery, lithium ion battery, nickel metal hydride battery, nickel cadmium battery, or other battery type configured to power electronic device 100 over many charging cycles. Alternatively or additionally, battery 120 may include a primary cell battery configured to be replaced when substantially discharged.

Battery 120 is shaped to provide a desired power capacity in a space-efficient configuration. In some embodiments, battery 120 has front and back major planar faces 121, 122 separated by minor sides 123, 124, 125, 126 defining a thickness (t) of battery 120. For example, sides 123, 125, may be parallel to top and bottom sidewalls 111, 113 of electronic device housing 110, and extend substantially across a width of electronic device housing 110, such as more than 50%, more than 75%, or more than 90% of the width of electronic device housing. Such a configuration promotes a relatively high power capacity for a battery having a particular power density.

In some embodiments, battery 120 is a lithium polymer battery including an electrode assembly within packaging 128. The electrode assembly 128 may include multiple sections or layers, such as a cathode layer, separator, anode layer, etc. The sections or layers are enclosed by packaging 128 (e.g., hermetically sealed within packaging 128). Battery 120 includes positive and negative electrode terminals 169a, 169b extending from packaging 128 that may be connected to first and/or second circuit board 130a, 130b to power electronic device 100. The positive and negative electrode terminals 169a, 169b are connected to with components of electrode assembly to receive electrical power that is generated by chemical reactions in the electrode assembly.

Battery 120 may include a first connector 161 and a second connector 162 connected to first circuit board 130a and second circuit board 130b. Battery 120 includes electrical conductors 165 that extend between first connector 161 and second connector 162. First circuit board 130a may thus be connected to second board 130b through battery 120 via electrical conductors 165. In various embodiments, electrical conductors 165 may be conductive lines, printed conductive traces, or other conductive components. In some embodiments, electrical conductors 165 provide the only electrical connection between first and second circuit boards 130a, 130b, such that the first and second circuit boards 130a, 130b are electrically isolated if not connected to battery 120 (e.g., and electronic device 100 may not function properly or at all.). In some embodiments, first and second electrical connectors 161, 162 are not connected to the electrode assembly and/or connection with first and second electrical connectors 161, 162 does not power electrical components of electronic device 100.

Battery 120 may include multiple electrical connections that can be configured to electrically connect first circuit board 130a with second circuit board 130b. For example, battery 120 may include a third electrical connector 163, a fourth electrical connector 164, and electrical conductors 166 extending between third and fourth electrical connectors 163, 164. In one example, electrical conductors 166 include an RF transmission line configured to transmit RF signals from first circuit board 130a (e.g., from a diversity antenna) to second circuit board 130b so as to reduce signal loss.

In some embodiments, packaging 128 of battery 120 may include a flexible pouch made of one or more substrate layers. Packaging 128 may enclose the electrode assembly, allow heat transfer away from the electrode assembly, provide an air and moisture barrier, and/or protect the electrode assembly from physical impact. Packaging 128 may include a flexible polyamide layer that extends around all (e.g., substantially all of the major faces and thickness of battery 120), and/or provides a substrate layer of electrical conductors 165 and 166, thermal transfer components, an NFC circuit, and/or other components. In some embodiments, packaging 128 does not include a continuous metallic layer (e.g., an aluminum layer entirely surrounding battery 120).

Circuit board 130 is configured to accommodate components of electronic device 100 in a space-efficient manner, and provide robust mechanical and electrical connections between these components. Circuit board 130 may support and/or electrically connect one or more components of electronic device 100 such as one or more of battery 120, microphone 133, speaker 134, sensors 135, camera assembly 136, flash devices 137, processor 138, electrical connectors (e.g., USB connectors, audio connectors, etc.), antenna lines, and/or other components. In some embodiments, first circuit board 130a is positioned at a top region of electronic device housing 110 and second circuit board 130b is positioned at a bottom region of electronic device housing 110. For example, electronic device housing 110 may be characterized by a length in the direction of a y-axis extending between top and bottom walls 111, 113, and a thickness in the direction of a z-axis transverse to the y-axis (e.g. extending in a direction between the display and the back major planar face 115). First and second circuit boards 130a, 130b, may be arranged along the y-axis such that first circuit board 130a is arranged at a top region within electronic device housing 110 and second circuit board 130b is arranged at a bottom region within electronic device housing. In some embodiments, back major face 115 of electronic device housing may include a logo, text, or other indicia that is right-side up when electronic device 100 is held such that first circuit board 130a is near the uppermost side wall and second circuit board 130b is near the lowermost side wall.

Battery 120 connects the first and second circuit boards 130a, 130b. First and second circuit boards 130a, 130b may be printed circuit boards, flexible circuit boards, other circuit board types, and/or combinations thereof.

First and second circuit boards 130a, 130b may be positioned at top and bottom positions of electronic device housing 110 so that various components may be accommodated at top and bottom regions of the electronic device. For example, first circuit board 130a is positioned at a top region of electronic device housing 110 and may include components beneficially positioned at the top region. First circuit board 130a may accommodate components such as an earpiece assembly including a speaker, front facing camera, proximity sensor, antenna lines, a microphone configured to receive audio from the external environment that may be processed to provide noise cancellation, camera flash, diversity antenna, and/or other components. In some embodiments, the speaker and/or proximity sensor are the only speaker and proximity sensor of electronic device 100, and are positioned on first circuit board 130a positioned at a top region of the electronic device 100. Second circuit board 130 is positioned at a bottom region of electronic device housing 110 and may include components beneficially positioned at the bottom region. Second circuit board may accommodate components such as an electrical connector (e.g., USB connectors, audio connectors, etc.), audio speaker, microphone to receive audio input from a user or the external environment, vibrator, and/or other components. In some embodiments, the electrical connector provides a charging port and is positioned on second circuit board 130b positioned at a bottom region of the electronic device 100. Such positioning may promote functionality and usability of the components by a user of electronic device 100.

Battery 120 may accommodate one or more other electrical components and/or electrically connect various components of first and second boards 130a, 130b. In some embodiments, battery 120 includes one or more of a hall effects sensor, battery thermistor, magnetometer, NFC circuit, or other electronic components. Battery 120 may electrically connect processor 138, on first circuit board 130a, for example, with the components of second circuit board 130b. In some embodiments, battery 120 provides the only electrical connection between first and second circuit boards 130a, 130b. Electronic device 100 may not include a flex conductor, for example, extending over battery 120 between first and second circuit boards 130a, 130b, and may not include a flex conductor extending over battery 120 (e.g., between battery 120 and display assembly 140) at all. Alternatively or additionally, electronic device 100 may not include an additional circuit board or circuit board portion extending along a side of battery 120 between first and second circuit boards 130a, 130b. In this way, battery 120 may occupy a greater volume of electronic device 100.

Additional space may be available within electronic device housing 110, particularly in an x-direction (e.g., because an additional circuit board is not required to connect first and second circuit boards 130a, 130b), as a result of electrical conductors 165 and/or 166 extending through battery 120. The additional space may be used to accommodate other components within electronic device housing 110. For example, electronic device housing 110 may accommodate a relatively larger battery 120 as a result of electrical conductors 165 and/or 166 that connect first and second circuit boards 130a, 130b. In some embodiments, battery 120 occupies substantially an entire space between first and second circuit boards 130a, 130b, and between sidewalls 112 and 114. Battery 120 may also occupy an entire space between back major planar face 115 of electronic device housing 110 and a rear-most portion of display assembly 140. As a result, battery 120 can have a relatively larger volume and power capacity such that electronic device 100 can operate for a longer period of time between charges.

Battery 120 may include additional electrical components arranged on a side defining a thickness of battery 120, including one or more user input mechanisms, such as a button or switch, that may be operated by user input along sidewall 114 of electronic device housing 110. For example, a user-actuatable button may be mounted on a side of battery 120 defining a thickness of battery 120. A user may actuate the button by pressing inwards along sidewall 114 of electronic device 110 such that the axis of actuation is parallel to the major planar face 121 of battery 120. Such a configuration can promote a robust electrical connection that can be reliably actuated through thousands of cycles without failure. Actuating in the direction of battery 120 can reduce the actuation force that could be placed on electrical connections between the button and battery 120, for example. Alternatively or additionally, battery 120 may include additional electrical components arranged on a major planar face of battery 120, such as an NFC circuit.

The material type, thickness, and number of layers of circuit board 130 may be selected to provide desired properties. For example, the substrate layers and electrical trace layers of first and second circuit boards 130a, 130b can be selected to affect the mechanical stiffness, insulating characteristics, and electrical impedance, for example, of the boards. In various embodiments, first and second circuit boards 130a and 130b include substrate layers made from FR-2 phenolic paper, FR-3 cotton paper, FR-4 epoxy resin-impregnated woven fiberglass, metal core board, polytetrafluoroethylene, polyimide, polyamide, combinations thereof, and/or other materials. The materials and characteristics of one or more conductive layers, such as conductive traces, can be selected based on mechanical and/or electrical properties. For example, the material and thickness of a conductive trace layer may be selected to provide a desired electrical impedance.

In some embodiments, the material layers and characteristics of first and second circuit boards 130a, 130b may differ from each other, and may be individually selected based on the configuration of electronic components of first and second circuit boards 130a, 130b. Similarly, characteristics of electrical conductors 165, 166 may be selected independent of characteristics of first and/or second circuit boards 130a, 130b. Independent design and configuration of first and second circuit boards 130a, 130b, and/or electrical conductors 165, 166 of battery 120 may facilitate design and assembly of circuit boards 130a, 130b, and/or battery 120. In some embodiments, battery 120 may include electrical conductors 165, 166 that are fewer and/or thinner than conductive traces of first and/or second circuit boards 130a, 130b, or vice versa. Electrical conductors 165, 166 connecting first and second circuit boards 130a, 130b, and separately formed from first and second circuit boards 130a, 130b, can thus further reduce the overall space required by circuit board 130, and may promote flexibility in accommodating other components within electronic device housing 110.

First and second circuit boards 130a and 130b are sized to fit within electronic device 100 and accommodate the desired electronic components. In some embodiments, first and second circuit boards have different sizes (e.g., different usable surface areas). First circuit board 130a is larger than second circuit board 130b, or vice versa.

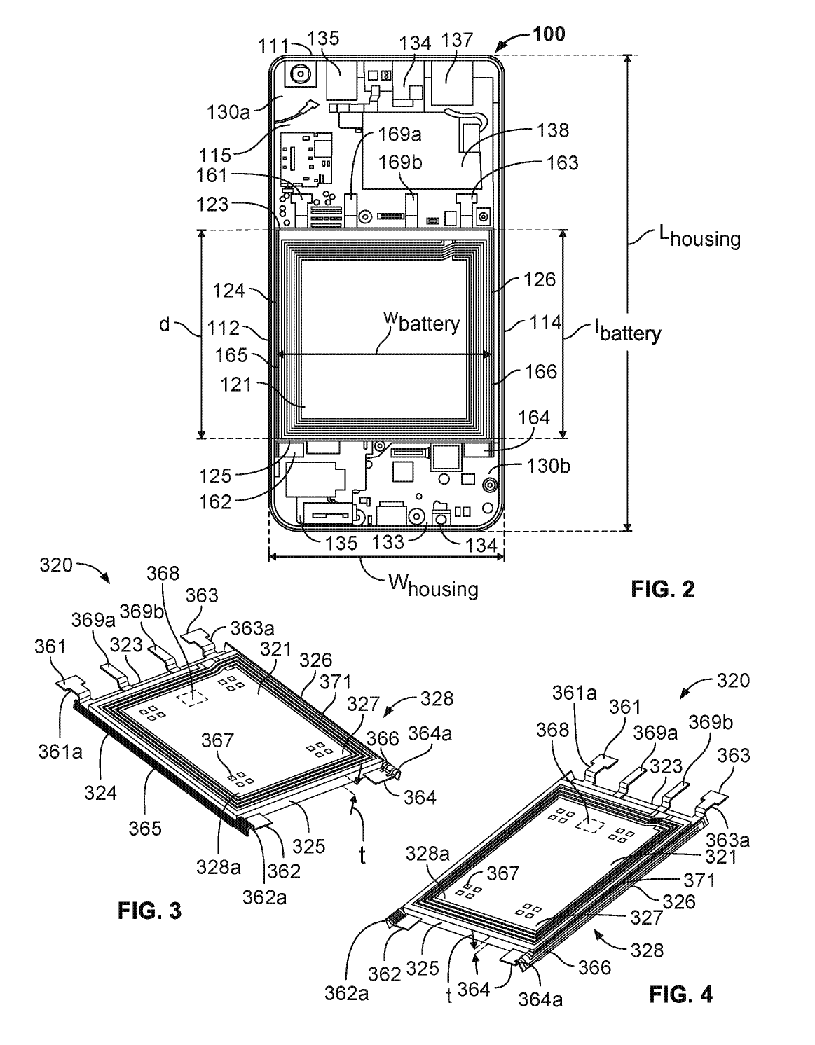

Referring to FIG. 2, first and second circuit boards 130a, 130b, are fixedly positioned within electronic device housing 110 and separated by a distance (d). One or more electrical conductors 165 and/or 166 of battery 120 extend partially or completely between first and second circuit boards 130a, 130b. For example, electrical conductors 165 and/or 166 extend between first and second circuit boards 130a, 130b and span distance (d). Electrical conductors 165 and/or 166 may thus span a length at least substantially equal to distance (d), and in some embodiments, greater than distance (d). For example, electrical conductors 165 and/or 166 extend between first, second, third, and/or fourth connectors 161, 162, 163, 164 and thus may be described as extending along or overlapping with portions of first and/or second circuit boards 130a, 130b (e.g., to facilitate electrical connection).

Distance (d) between first and second circuit boards 130a, 130b, may provide a space in which battery 120 is accommodated. Battery 120 has a length (l_{battery}) between minor sides 123, 125, (e.g., sides oriented parallel to top and bottom sidewalls 111, 113 of electronic device housing 110), and a width (w_{battery}) between minor sides 124, 126 (e.g., sides oriented substantially parallel to side portions 112, 114). In some embodiments, length (l_{battery}) is equal to distance (d) such that battery 120 occupies substantially the entire distance between first and second circuit boards 130a, 130b. Alternatively or additionally, there may be no electrical components between battery 120 (e.g., sidewalls of battery 120) and first and second circuit boards 130a, 130b, respectively. Such a configuration allows battery 120 to accommodate a maximum distance between first and second boards 130a, 130b to improve the power capacity of battery 120. Alternatively or additionally, distance (d) may be greater than 50% of length (L_{housing}) of electronic device housing 110. Such relative dimensions provide a space for battery 120 that accounts for a significant portion of the interior volume of electronic device 100. Battery 120 may thus be relatively large and provide a relatively high power capacity and facilitate an extended period of time between charges.

Little or no space may exist between sidewalls of battery 120 and first and/or second circuit board 130a, 130b when assembled. For example, a distance between sidewall 123 of battery 120 and first circuit board 130a may be less than 2.0 mm, less than 1.0 mm, less than 0.5 mm, less than 0.2 mm, or 0 mm (e.g., such that sidewall 123 is in contact with first circuit board 130a), and a distance between sidewall 125 of battery 120 and second circuit board 130b may be less than 2.0 mm, less than 1.0 mm, less than 0.5 mm, less than 0.2 mm, or 0 mm (e.g., such that sidewall 125 is in contact with second circuit board 130b). Distance (d) may provide a space within electronic device housing in which no electronic components are accommodated except battery 120. In some embodiments, only battery 120, and no separate electrical components, are accommodated in a space surrounded by first and second circuit boards 130a and 130b, and walls 112, 114 of electronic device housing 110.

Electronic device housing 110 has a width (W_{housing}) between walls 112, 114 and a length (L_{housing}) between walls 111, 113. In some embodiments, width (W_{housing}) between walls 112, 114 is entirely occupied by battery 120 at locations where battery 120 is present. For example, distances between sidewalls 124, 126 of battery 120 and walls 112, 114 of electronic device housing 110, respectively, may be less than 2.0 mm, less than 1.0 mm, less than 0.5 mm, less than 0.2 mm, or 0 (e.g., such that battery 120 is in contact with walls 112, 114). In various embodiments, width (w_{battery}) is greater than 80%, greater than 85%, greater than 90%, greater than 95%, or greater than 98% of width (W_{housing}) of electronic device housing 110 between inner surfaces of walls 112, 114. Such relative dimensions can facilitate a battery 120 having a relatively large width (w_{battery}) while an electrical connection between first circuit board 130a and second board 130b is provided through electrical conductors 165 and/or 166 of battery 120.

First and second circuit boards 130a, 130b may extend across substantially the entire width (W_{housing}) of electronic device housing 110. In some embodiments, first and second circuit boards 130a, 130b extend along less than the entire (L_{housing}) (e.g., because first and second circuit boards are separated by battery 120). Electrical conductors 165, 166 of battery 120 electrically connect first and second circuit boards 130a, 130b that are spaced apart from one another. In one example, first circuit board 130a, second circuit board 130b, and electrical conductors 165 and/or 166 together extend along the entire length (L_{housing}) of electronic device housing 110 (e.g., substantially an entire length, such as 90% or more of the length).

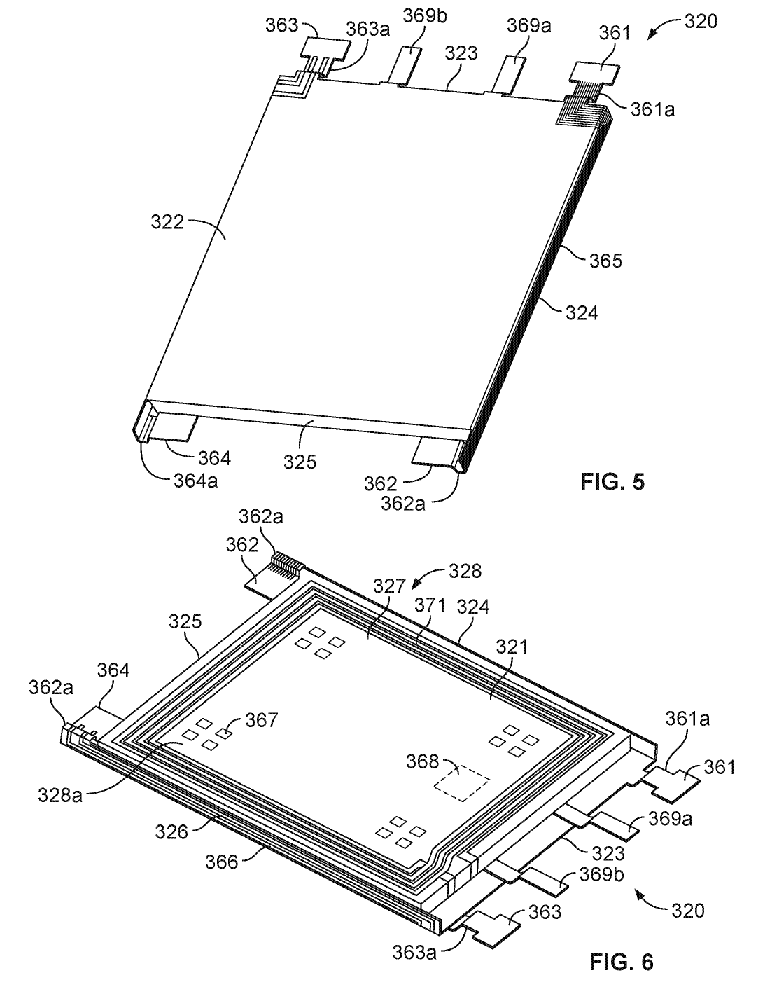

Referring to FIGS. 3-6, perspective views of an example battery 320 are shown. In various embodiments, battery 320 may be suitable for use with electronic device 100 and have features similar to battery 120, described herein. Battery 320 includes first and second electrical connectors 361, 362, third and fourth electrical connectors 363, 364, and positive and negative electrode terminals 369a, 369b. Electrical conductors 365 extend between first and second electrical connectors 361, 362, and electrical conductors 366 extend between third and fourth electrical connectors 363, 364.

Battery 320 is shaped to provide a desired power capacity in a space-efficient configuration, and may include front and back major planar faces 321, 322 separated by minor sides 323, 324, 325, 326 defining a thickness (t_{thickness}) of battery 320. For example, battery 120 may be configured for assembly with an electronic device housing such that sides 323, 325 are parallel to top and bottom sidewalls of the electronic device housing (e.g., such as top and bottom sidewalls 111, 113 of electronic device housing 110). In some embodiments, first and third electrical connectors 361, 363 are positioned proximate side 323, and second and fourth electrical connectors 362, 364 are positioned proximate side 325 (e.g., opposite from side 323). Electrical conductors between first and second connectors 361, 362, and/or third and fourth connectors 363, 364, respectively, may thus span an entire dimension of battery 320 between side 123 and side 125, for example. In some embodiments, battery 320 has a non-rectangular and/or irregular shape, stepped edges, etc.

Electrical conductors 365, 366 are configured to provide electrical communication between first and second electrical connectors 361, 362, and third and fourth electrical connectors 363, 364, respectively. In some embodiments, electrical conductors 365 are signal lines configured to carry electrical signals between first and second circuit boards connected to first and second electrical connectors 361, 362. Electrical conductors 366 may be RF transmission lines configured to carry RF signals between first and second circuit boards connected to third and fourth electrical connectors 363, 364, such as between a diversity antenna on the first circuit board and the second board. In some embodiments, RF transmission lines may be larger (e.g., have a greater width and/or thickness) compared to the signal lines of electrical conductors 355, for example. A relatively larger width may provide reduced impedance and reduced transmission losses of the RF transmission (e.g., transmitted from a diversity antenna). In some embodiments, an additional RF transmission line connecting first and second circuit boards (e.g.,separate from battery 320), is not necessary and not present in an electronic device powered by battery 320.

Electrical conductors 365 may extend between sides 323 and 325 at least partially along side 324. For example, electrical conductors 365 extend at least partially along a side defining a thickness (t) of battery 320. Electrical conductors 365 positioned along a thickness may facilitate a large volume of electrode assembly 327 of battery 320, particularly by facilitating a larger thickness (t). In some embodiments, electrical conductors 365 are only on sides 324 and/or 325, and are not present on major planar faces 321, 322 of battery 320.

Alternatively or additionally, electrical conductors 365 may extend at least partially along a major planar face of battery 320, such as along major planar faces 321 and/or 322. Electrical conductors 365 positioned along a major planar face may facilitate a large volume of an electrode assembly 327 of battery 320, particularly by facilitating a larger width (e.g., between sides 324 and 326). In some embodiments, electrical conductors 365 are only on major planar faces 321 and/or 322, and are not present on sides 324, 325, for example, that define a thickness (t) of battery 320.

First and second electrical connectors 361, 362, and third and fourth electrical connectors 363, 364 are configured to connect with complementary connectors of first and second circuit boards of an electronic device. First and second connectors 361, 362, third and fourth connectors 363, 364, and respective complementary connectors are configured to provide secure electrical connections. First, second, third and/or fourth connectors 361, 362, 363, 364 may include a board-to-board connector, zero insertion force (ZIF) connector, micro-coaxial connector, combinations thereof, and/or other connectors that provide a secure electrical connection.

Electrical connectors 361, 362, 363, and/or 364 of battery 120 may include arm portions 361a, 362a, 363a, 364a configured to accommodate a selected respective positioning of battery 320 and one more components to which battery 320 may be connected. Arm portions 361a, 362a, 363a, and/or 364a may extend upwards and inwards, for example, including multiple bends (e.g., such as approximately 90° bends) so that connectors 361, 362, 363, and/or 364 are positioned for secure connection and/or are not unduly strained. In some embodiments, connectors 361, 362, 363, and/or 364 may be flexible such that the connector ends can be moved into a desired position. Arm portions that are flexible and/or include bends may facilitate assembly by accommodating a larger manufacturing tolerance range while providing reliable connectability.

The material types and geometry of the packaging 328 of battery 320 may be selected to provide a battery 320 that has desired characteristics. In some embodiments, packaging 328 of battery 320 is a pouch-type packaging that includes one or more layers surrounding electrode assembly 327. Electrode assembly 327 may include multiple sections or layers, such as a cathode layer, separator, anode layer, etc. Packaging 328 may include a flexible polymer layer completely surrounding electrode assembly 327 of battery 320 that may protect and seal electrode assembly 327, and/or provide other features and characteristics of battery 320.

In some embodiments, packaging 328 may include a flexible circuit substrate layer that includes one or more layers configured to provide a substrate of a flexible printed circuit. Electrical conductors 365, 366, NFC circuit 371, and/or other electrical components may be printed or otherwise applied directly to the flexible circuit substrate layer of packaging 328. The flexible polymer layer of packaging 328 may thus provide both a layer of the pouch of battery 320 and a printed circuit substrate to which electrical conductors may be applied. In some embodiments, the flexible circuit layer completely surrounds internal components of battery 320 (e.g., flexible circuit substrate layer completely surrounds and encloses electrode assembly 328), and/or may be the only layer of packaging 328 that completely surrounds internal components of battery 320 (e.g., such that packaging 328 does not include a continuous metal foil layer that completely surrounds internal components of battery 320).

In some embodiments, packaging 328 may provide both a pouch surrounding electrode assembly 327 and a substrate of a circuit, such as a flexible printed circuit. Such configurations may increase the volume available within an electronic device for electrode assembly 327 or other components. For example, an additional circuit board or electrical connections to connect circuit boards positioned on opposite sides of battery 320 can be eliminated because battery 320 itself can provide electrical connections between circuit boards connected to first and second electrical connectors 361, 362, and third and fourth electrical connectors 363, 364. The additional space can be used to provide a large battery 320, house additional components, or reduce the overall size of an electronic device powered by battery 320.

In some embodiments, electrical conductors 365 and/or 366 provide the only electrical connection between first and second circuit boards connected to first and second electrical connectors 361, 362, and/or third and fourth electrical connectors 363, 364, such that the first and second circuit boards are electrically isolated if not connected to battery 320 (e.g., and the electronic device may not function properly or at all).

Packaging 328 may include one or layers that completely or partially surround electrode assembly 327, such as one or more sealant layers, insulating layers, and/or structural layers. In various embodiments, packaging may include a layer include a polyolefin polymer, such as polypropylene, polyethylene, or ethylene-propylene copolymer, polyether ether ketone, aliphatic or semi-aromatic polyamides, a metal foil, such as aluminum, steel, nickel, or other metal layers that provides durability, prevents air from entering the pouch, and/or provides selected thermal transfer characteristics.

Packaging 328 may include one or more components applied or otherwise supported by flexible circuit substrate layer. For example, a metallic material 367 may be printed, laminated, or otherwise applied to the flexible circuit substrate layer. Metallic material 367 may facilitate dissipation of heat from electrode assembly 327 of battery 320. For example, metallic material 367 is laminated in an array or pattern on major planar faces 321, 322, and one or more sides of battery 320. In some embodiments, metallic material 367 is discontinuous and does not form a continuous layer surrounding battery 320.

Battery 320 may include a battery protection circuit 368. Battery protection circuit 368 may be configured to limit battery cell voltage, current, etc., and open circuit the battery when a threshold is reached. In some embodiments, battery protection circuit 368 may be a printed circuit supported by the flexible circuit substrate layer of packaging 328. A battery protection circuit 368 applied directly to a layer of packaging 328 of battery 320 can provide a smaller battery size and/or increase the volume available for electrode assembly 327. In this way, the performance of battery 320 may be increased, and/or the size of an electronic device powered by battery 320 reduced.

Battery 320 may include one or more additional electrical components supported by flexible circuit substrate layer of packaging 328. In one embodiment, battery 320 includes an NFC circuit 371. NFC circuit may be printed or otherwise applied to flexible circuit substrate layer of packaging 328. For example, NFC circuit 371 may include conductive traces positioned on a major planar face 321, and/or 322, such as looped proximate the perimeter of a major planar face 321 and or 322. NFC circuit 371 may include end regions 371a, 371b, electrically connected with other components of NFC circuit within battery 120, and/or configured for connection with electrical components of a circuit board, such as via a spring connection. An NFC circuit provided on a flexible circuit substrate layer 328a that forms a pouch of packaging 328 improves space efficiency of battery 320 by eliminating an additional substrate layer that may otherwise be required to support components of NFC circuit. Alternatively or additionally, battery 320 includes a conductive charging circuit. The conductive charging circuit may be partially or completely provided on the flexible circuit substrate layer of packaging 328.

Packaging 328 may include a printable layer configured to receive printed indicia. For example, flexible circuit substrate layer 328a may be printable such that labeling can be printed directly on flexible circuit substrate layer 328a (e.g., instead of including an additional label applied to battery 320). Printing necessary indicia on a flexible circuit substrate layer 328, such as a flexible circuit substrate layer 328a that defines a pouch surrounding electrode assembly 327 and that provides a substrate of electrical components of battery 320, improves space efficiency by reducing or eliminating additional components. Space otherwise necessary to accommodate a label may be used to increase the volume of electrode assembly 327 and/or reduce the overall dimensions of an electronic device powered by battery 320.

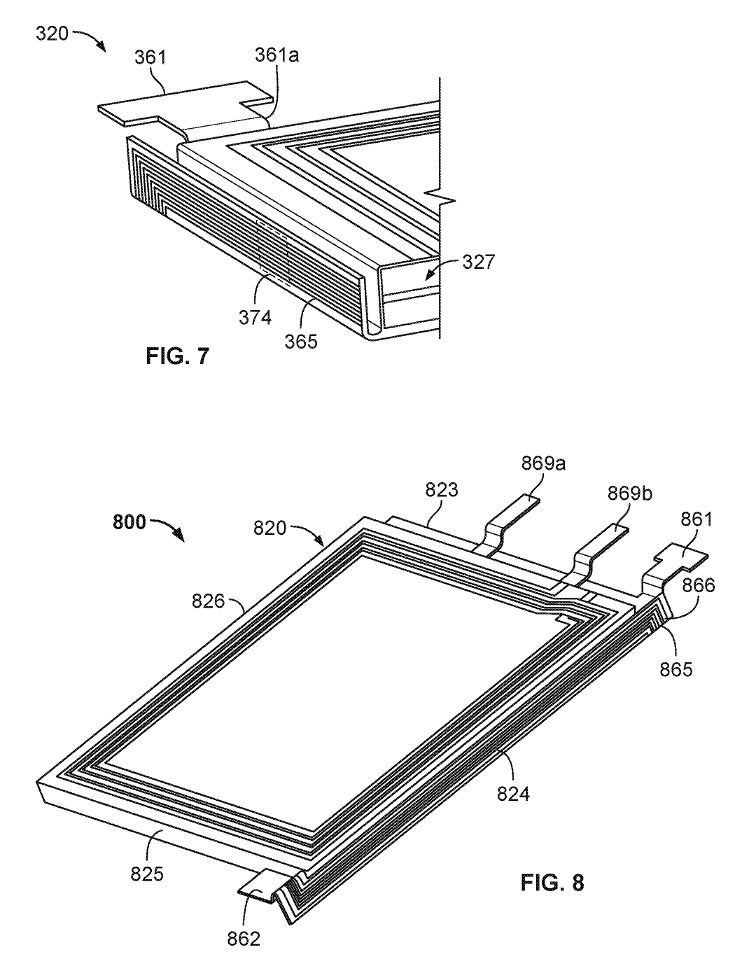

Referring to FIG. 7, a partial view of battery 320 is shown, including side 324 and electrical conductors 365 extending along side 324. Electrical conductors 365 may be positioned proximate a seam or joined portion of packaging 368. In some embodiments, manufacture of battery 320 includes operations of wrapping electrode assembly 327 in packaging 328, such as flexible circuit substrate layer 328a, and sealing the packaging 328 to enclose electrode assembly 327. Heat and/or pressure may be applied to melt flexible circuit substrate layer 328a, and/or an adhesive or other layer, to enclose electrode assembly 327. Such a seal may be present proximate side 324. In some embodiments, electrical conductors 365 are positioned on an extension or flap region 374 of packaging 328 that extends outwardly from a sealing location 375 of packaging 328. Such a configuration can facilitate manufacturing and assembly of battery 328 by positioning electrical conductors near an edge of the flexible circuit substrate layer 328a before it is folded or otherwise formed into a pouch to enclose electrode assembly 327.

In some embodiments, electrical conductors 365 extending between first and second electrical connectors 361, 362 are arranged in a vertical configuration. For example, electrical conductors 365 are positioned above and below one another along side 324 between major planar face 321 and major planar face 322. Alternatively or additionally, electrical conductors 365 may be arranged in a single plane on flexible circuit substrate layer 328a. A vertical arrangement of electrical conductors 365 may promote space efficiency, and/or increase the volume available for electrode assembly 327. In some embodiments, such a configuration can facilitate a battery 320 that occupies an entire width of an electronic devices housing (e.g., such that walls 324, 325 are flush against opposite walls of the electronic device housing. Alternatively or additionally, one or more electrical components 374 can be arranged in a vertical configuration connected with one or more electrical conductors 365. Electrical component 374 may include a hall effects sensor, battery thermistor, magnetometer, button components, or other electronic components.

Referring to FIG. 8, an example battery 820 of an electronic device 800 is shown, including first and second connectors 861, 862, positive and negative electrode terminals 869a, 869b, and electrical conductors 865, 866 extending between first and second connectors 861, 862. In various embodiments, electronic device 800 and battery 820 may have features similar to electronic devices 100, 300, and batteries 120, 320, described herein. Battery 820 is positionable within an electronic device housing together with other components of electronic device 800.

In some embodiments, battery 820 includes electrical conductors 865 and electrical conductors 866 extending between first and second connectors 861, 862. Electrical conductors 865, 866 may be conductive lines configured to provide communication between components of first and second circuit boards connected to first and second electrical connectors 861, 862. For example, electrical conductors 865 may be relatively thinner lines and electrical conductors 866 may be relatively thicker lines, such as RF transmission lines. Both electrical conductors 865 and 866 may be connectable via first and second connectors 861, 862, respectively, and/or extend along a common side (e.g., side 824) of battery 820 between opposite ends

Positive and negative electrode terminals 869a, 869b may be separate or included with first connector 861 (e.g., such that a connection with a single connector results in connection with the positive and negative electrode terminals 869a, 869b, and electrical conductors 865, 866. In some embodiments, positive and negative electrode terminals 869a, 869b, and first connector 861 extend outwardly at a single location, and thus provide a single connector to join with a circuit board for example. Such a configuration may improve manufacturing and assembly be requiring assembly of a single connector (e.g., including isolated electrical connections for the positive electrode terminal 869a, negative electrode terminal 869b, and electrical conductors 865).

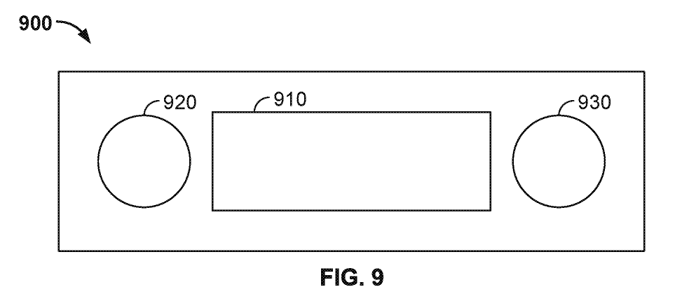

Referring, to FIG. 9, an example connector 900 is shown that can be used to connect a battery, such as battery 120, 320, 820, with first and second circuit boards, such as first and second circuit boards 130a, 130b. Connector 900 includes a central connector 910 and side connectors 920, 930 spaced on each side of central connector 910 such that central connector 910 and side connectors 920, 930 are arranged in a row. In some embodiments, central connector 910 includes a board-to-board type connector and side connectors 920, 930 include micro-coax connectors. The board-to-board connector provides reliable and compact electrical connection. The micro-coax connector can provide additional electrical connections, such as for RF transmission lines, and also serve as retention pins, providing additional mechanical robustness to the connection.

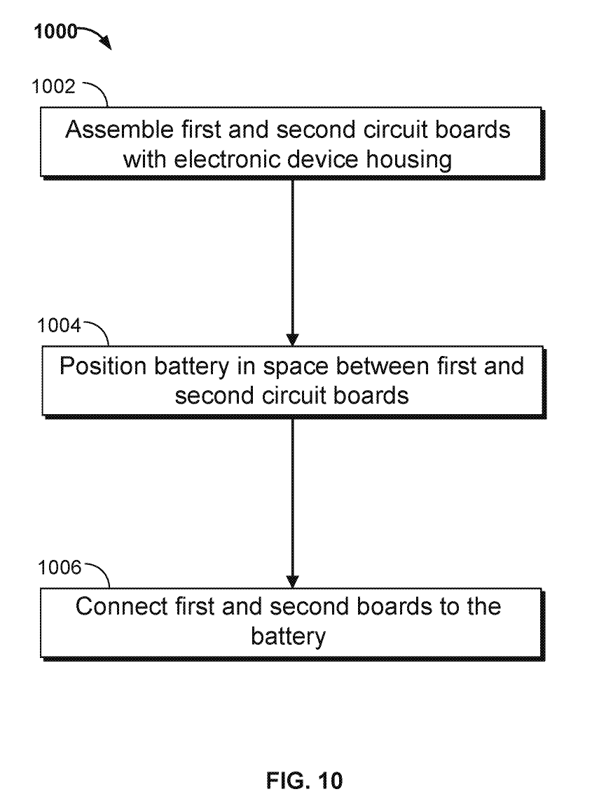

Referring to FIG. 10, a flow diagram of an example method 1000 of manufacturing an electronic device is shown. In some embodiments, method 1000 includes operation 1002 of assembling first and second circuit boards with an electronic device housing. For example, first and second circuit boards may be arranged at top and bottom regions of the electronic device, respectively. Operation 1002 may further include securing the first and second circuit boards in a fixed position within the electronic device housing. The circuit board may be brought into engagement with one or more complementary features of the electronic device housing and fixed into position relative to the electronic device housing. The circuit board may be secured using one or more snap-fit connectors, adhesives, welds, or other fastening techniques.

Method 1000 further includes operation 1004 of positioning a battery in the space between the first and second circuit boards (or between locations at which the first and second circuit boards would be located, in those examples in which the battery is positioned before the circuit boards). The space may be at least partially defined by the first and second circuit boards (e.g., a distance between the first and second circuit boards), and/or may be at least partially defined by the electronic device housing. In some embodiments, the space is a substantially rectangular space defined by the first and second circuit boards on opposite sides, and side walls of the electronic device housing on opposite sides. The battery may occupy substantially the entire space. In some embodiments, no other components are positioned in the space along with the battery.

Method 1000 further includes operation 1006 of connecting the first and second circuit boards to the battery to provide electrical communication between the first and second circuit boards through the battery. In some embodiments, the first circuit board is connected to a first electrical connector of the battery, and the second circuit board is connected to a second electrical connector of the battery positioned on an opposite side of the battery from the first electrical connector. In some embodiments, connection of the first circuit board to the first electrical connector and connection of the second circuit board to the second electrical connector provides the only electrical communication between the first and second circuit boards. For example, the first and second circuit boards could not electrically communicate, and the electronic device would not function properly, but for connection of the first and second circuit boards to one another via the battery, in some embodiments.

Operations 1002, 1004, and 1006 may be performed in any suitable order. In some embodiments, the battery is positioned in the electronic device housing in an initial manufacturing step before the first and second circuit boards are positioned in the electronic device housing. In other embodiments, the first and second circuit boards and the battery may first be connected, and subsequently positioned within the electronic device housing together.

While this specification contains many specific implementation details, these should not be construed as limitations on the scope of the disclosed technology or of what may be claimed, but rather as descriptions of features that may be specific to particular embodiments of particular disclosed technologies. Certain features that are described in this specification in the context of separate embodiments can also be implemented in combination in a single embodiment in part or in whole. Conversely, various features that are described in the context of a single embodiment can also be implemented in multiple embodiments separately or in any suitable subcombination. Moreover, although features may be described herein as acting in certain combinations and/or initially claimed as such, one or more features from a claimed combination can in some cases be excised from the combination, and the claimed combination may be directed to a subcombination or variation of a subcombination. Similarly, while operations may be described in a particular order, this should not be understood as requiring that such operations be performed in the particular order or in sequential order, or that all operations be performed, to achieve desirable results. Particular embodiments of the subject matter have been described. Other embodiments are within the scope of the following claims.

What is claimed is:

1. An electronic device, comprising:
a battery comprising a first electrical connector at a first end of the battery, a second electrical connector at a second end of the battery, and one or more electrical conductors extending from the first connector to the second connector;
a first circuit board connected to the first connector; and
a second circuit board connected to the second connector,
wherein the first circuit board is electrically connected to the second circuit board by the one or more electrical conductors.

2. The electronic device of claim 1, wherein the first circuit board is electrically connected to the second circuit board only by the one or more electrical conductors of the battery.

3. The electronic device of claim 1, further comprising a display connected to the first circuit board, wherein:
the first circuit board includes at least one of: a speaker, a front facing camera, a proximity sensor, a microphone, and a camera flash, and
the second circuit board includes at least one of: an electrical connector, an audio connector, a microphone, and a vibrator.

4. The electronic device of claim 1, further comprising positive and negative electrode terminals electrically connected to an electrode assembly of the battery, the positive and negative electrode terminals configured to receive electrical power that is generated by chemical reactions in the electrode assembly.

5. The electronic device of claim 1, wherein the battery comprises a pouch and an electrode assembly within the pouch.

6. The electronic device of claim 5, wherein the pouch comprises a flexible circuit substrate layer at least partially surrounding the electrode assembly.

7. The electronic device of claim 6, wherein the flexible circuit substrate layer comprises a polyamide.

8. The electronic device of claim 6, wherein the flexible circuit substrate layer comprises a battery protection circuit.

9. The electronic device of claim 6, wherein the flexible circuit substrate layer comprises an NFC circuit.

10. The electronic device of claim 9, wherein the flexible circuit substrate layer comprises RF transmission lines.

11. The electronic device of claim 1, further comprising an electronic device housing, wherein the first circuit board is positioned in a top region of the housing and the second circuit board is positioned in a bottom region of the housing.

12. The electronic device of claim 11, wherein the battery is positioned between the first circuit board and the second circuit board.

13. The electronic device of claim 1, wherein the first circuit board, the second circuit board, and the electrical conductors of the battery together extend along an entire length of the electronic device housing, and the first circuit board and the second circuit board each extend across an entire width of the electronic device housing.

14. The electronic device of claim 1, wherein the battery has first and second major planar faces separated by sidewalls, the first major face and the second major face oriented parallel to the first circuit board and the second circuit board.

15. The electronic device of claim 14, wherein the electrical conductors extend along a sidewall of the battery between the first connector and the second connector.

16. An electronic device battery, comprising:
an electrode assembly;
a pouch surrounding the electrode assembly and including a flexible circuit substrate layer;
a first electrical connector at a first end;
a second electrical connector at a second end; and
one or more electrical conductors extending from the first connector to the second connector on the flexible circuit substrate layer.

17. The electronic device battery of claim 16, wherein the flexible circuit substrate layer comprises a battery protection circuit.

18. The electronic device battery of claim 16, wherein the one or more electrical conductors are not electrically connected with the electrode assembly.

19. A method of manufacturing an electronic device, comprising:
securing a first circuit board at a first position within an electronic device housing;
securing a second circuit board at a second position within the electronic device housing;
positioning a battery in a space within the electronic device housing defined between the first position and the second position, the battery having a first electrical connector, a second electrical connector, and one or more electrical conductors between the first and second electrical connectors; and
connecting the first circuit board to the first electrical connector and the second circuit board to the second electrical connector.

20. The method of claim 19, wherein the battery provides an only electrical connection between the first circuit board and the second circuit board.
